(19) United States
(12) Patent Application Publication
(10) Pub. No.: US 2014/0190728 A1
(43) Pub. Date: Jul. 10, 2014

(54) CIRCUIT BOARD AND METHOD FOR MANUFACTURING THE SAME

(71) Applicant: ECOCERA OPTRONICS CO., LTD., Taoyuan County (TW)

(72) Inventors: Cheng-Feng Chou, Taoyuan County (TW); Hung-Pin Lee, Taoyuan County (TW); Tzu-Yuan Lin, Taoyuan County (TW)

(73) Assignee: ECOCERA OPTRONICS CO., LTD., Taoyuan County (TW)

(21) Appl. No.: 13/831,291

(22) Filed: Mar. 14, 2013

(30) Foreign Application Priority Data
Jan. 7, 2013 (TW) 102100479

(51) Int. Cl. H05K 3/00; H05K 3/42; H05K 1/05; H05K 1/02; H05K 1/11; H05K 1/03

(52) U.S. Cl. CPC H05K 3/0088; H05K 1/115; H05K 1/0306; H05K 1/05; H05K 1/0201; H05K 3/423
USPC 174/252; 174/266; 174/255; 216/17; 205/125

(57) ABSTRACT

The invention provides a method for manufacturing a circuit board comprising the steps of: (a) forming a through hole in a substrate; (b) providing a photo resist to cover a predetermined area adjacent to the through hole on a first surface and a second surface opposite to the first surface of the substrate; and (c) performing an etching process to make the through hole has a shape of dumbbell.

### BACKGROUND OF THE INVENTION

1. Field of the Invention

The present invention generally relates to a circuit board and method for manufacturing the circuit board, in particular to the circuit board with a through hole having a shape of dumbbell.

2. Description of Related Art

Electrical connections between different interlayers in a circuit board can be achieved by forming through holes in the substrate and electroplating conductive materials in the through holes. The through hole can be formed by mechanical drilling such as drill bits or laser drilling. Alternatively, sandblasting process can be used. The through hole is formed to have the same diameter from the first surface to the second surface of a substrate by drill bits. The through hole is formed to have the same diameter from the first surface to the second surface of a substrate or a larger diameter on the first surface than the second surface of the substrate depends on energy distribution of laser beam.

A through hole with a dumbbell shape was proposed to solve the problem of the unfilled area of conductive material in the central part of the through hole. Because the through hole is wider at each end than at a center at a level between two surfaces of the substrate, the unfilled area of conductive material in the central part of the through hole can be prevented. A first hole that is getting narrower toward a central part is formed at a first side of a substrate by laser beam, and a second hole that is opposite to and connecting to the first hole and getting narrower toward the central part is formed at a second side of the substrate by laser beam. Accordingly, a through hole with a dumbbell shape is formed by the above process.

Alternatively, a first hole that is getting narrower toward a central part is formed at a first side of a substrate by sandblasting process, and a second hole that is opposite to and connecting to the first hole and getting narrower toward the central part is formed at a second side of the substrate by sandblasting process. Accordingly, a through hole with a dumbbell shape is formed by the above process.

The above conventional methods may solve the problem of the unfilled area of conductive material in the central part of the through hole. However, those methods still have drawbacks such as mass production cannot be achieved and the cost of production is expensive.

### SUMMARY OF THE INVENTION

The present invention is provided to solve the problems of the prior art. One primary object and purpose of the invention is to provide a circuit board and method for manufacturing the circuit board. The method for manufacturing the circuit board may form a through hole with a shape of dumbbell which is getting narrower toward a central part from two surfaces of the substrate by etching a through hole with an identical diameter from one surface to the other surface of the substrate. The through hole with a shape of dumbbell can enhance yield of manufacturing conductive pillars.

In order to fulfill the object and purpose described above, the invention provides a method for manufacturing a circuit board comprising the steps of (a) forming a through hole in a substrate; (b) providing photo resist to cover a predetermined area adjacent to the through hole on a first surface and a second surface opposite to the first surface of the substrate; and (c) performing an etching process to the through hole so that the through hole has a shape of dumbbell.

Compared to laser drilling from one side of a substrate, the method for manufacturing a circuit board of the invention may form a through hole with a shape of dumbbell which is getting narrower toward a central part from two surfaces of the substrate by etching a through hole with an identical diameter from one surface to the other surface of the substrate. The etching process is performed by immersing the substrate into an etching solution with a temperature of 50-70° C. for 0.5-1 hour. The suitable composition of the etching solution includes 50-70 wt % H3PO4, 10-20 wt % HNO3, 10-20 wt % CH3COOH and 5-10 wt % deionized water. The etching solution may enter and etch the through hole from the first surface and the second surface for a period of time so that the diameters of the through hole at two ends are getting narrower toward the central part, but the central part of the through hole keeps substantially the same diameter. After etching a longer time, the diameter of the through hole from each of the first and second surfaces is continuously getting narrower toward the central part, which does not keep the same diameter anymore. Accordingly, different kinds of the dumbbell-shaped through hole can be achieved by controlling the immersing time of the substrate in the etching solution.

The through hole with a shape of dumbbell may advantageously form conductive pillars by the sputtering process, and prevent the through hole broken. Moreover, because the diameters at the two ends are larger than the diameter of the central part of the through hole, an electroplating solution can flow into the through hole without obstruction, and thus the unfilled area of conductive material in the central part of the through hole can be prevented.

Moreover, one aspect of the invention is to provide a circuit board comprising a substrate and a through hole formed in the substrate. The through hole has a shape of dumbbell which is getting narrower toward a central part from two surfaces of the substrate. The inner wall of the through hole has a surface roughness (Ra) of 0.3-0.4 μm. The through hole has diameters about 60-100 μm on the two surfaces of the substrate. Also, the through hole has a diameter at the central part of the substrate less about 20-30 μm than the diameters on the two surfaces of the substrate.

Another aspect of the invention is to provide a circuit board comprising a substrate and a through hole formed in the substrate. The through hole has a shape of dumbbell which is getting narrower toward a central part from two surfaces of the substrate, and the central part of the through hole keeps substantially the same diameter.

### BRIEF DESCRIPTION OF DRAWING

The features of the invention believed to be novel are set forth with particularity in the appended claims. The invention itself however, may be best understood by reference to the following detailed description of the invention, which describes an exemplary embodiment of the invention, taken in conjunction with the accompanying drawings, in which:

FIG. 1 is a flow chart of a method for manufacturing a circuit board of an embodiment according to the invention;

FIG. 2 is a cross-sectional view of a through hole that is formed in the substrate by using a laser beam of an embodiment according to the invention;

FIG. 3 is a cross-sectional view of a photo resist that covers a predetermined area adjacent to the through hole on a first surface and a second surface opposite to the first surface of the substrate;

FIG. 4 is a cross-sectional view of a through hole that is etched by performing an etching process;

FIG. 5 is a cross-sectional view of a through hole which is getting narrower toward a central part from two surfaces of the substrate, and the central part of the through hole keeps substantially the same diameter; and

FIG. 6 is a cross-sectional view of a through hole which is getting narrower toward a central part from two surfaces of the substrate.

### DETAILED DESCRIPTION OF THE INVENTION

In cooperation with attached drawings, the technical contents and detailed description of the present invention are described thereinafter according to a preferable embodiment, being not used to limit its executing scope. Any equivalent variation and modification made according to appended claims is all covered by the claims claimed by the present invention.

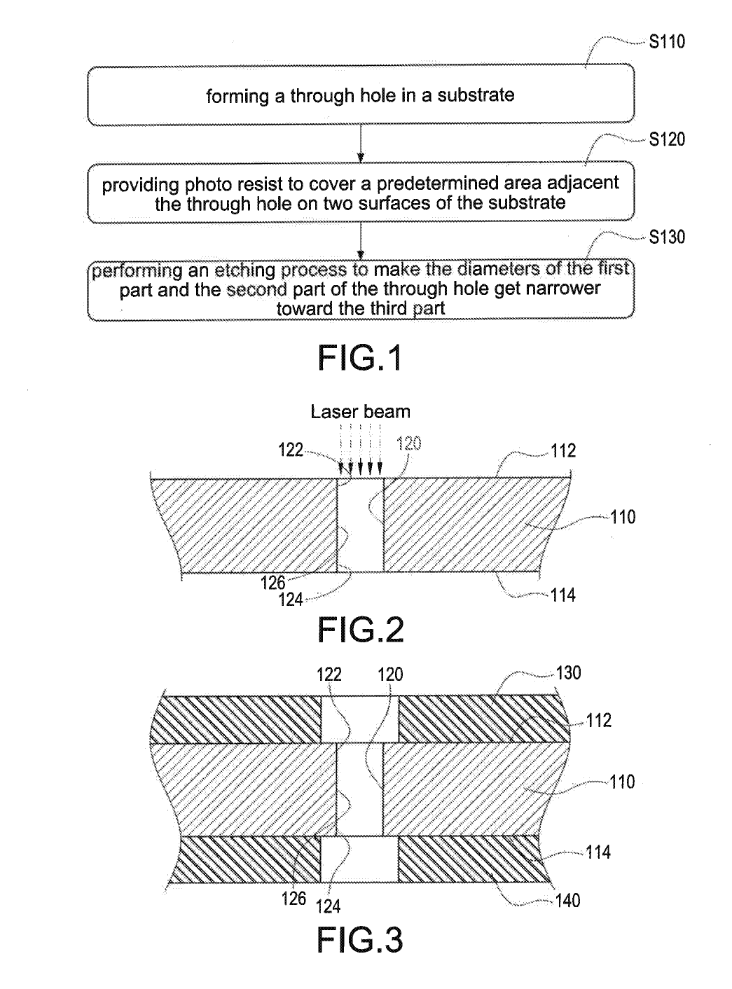

FIG. 1 shows a flow chart of method for manufacturing a circuit board of an embodiment of the invention. FIGS. 2-5 show cross-sectional views of a circuit board of manufacturing method of an embodiment of the invention. Please refer to FIG. 1. At first, in step S110, a through hole is formed in a substrate. The substrate has a first surface and a second surface opposite to the first surface of the substrate. The through hole includes a first part adjacent to the first surface, a second part adjacent to the second surface and a third part located between the first part and the second part. Please refer to FIG. 2. The substrate 110 is material of aluminum oxides or aluminum nitrides; aluminum or aluminum alloy; and copper or copper alloy. The through hole may be formed by mechanical drilling or laser drilling.

In the embodiment, a laser machine (not shown in the FIG. 2) is provided and near the substrate 110 at one side. A through hole 120 is formed in the substrate 110 by a laser beam with high energy emitted from the laser machine. The substrate 110 has a first surface 112 and a second surface 114 opposite to the first surface 112 of the substrate 110. The through hole 120 includes a first part 122 adjacent to the first surface 112, a second part 124 adjacent to the second surface 114 and a third part 126 located between the first part 122 and the second part 124. In the embodiment, the through hole 120 is formed to have the same diameter from the first surface 112 to the second surface 114. Alternatively, the through hole 120 is formed to have a larger diameter at the first surface 112 than the second surface 114 by adjusting energy distribution of laser beam.

Next, in step S120, a photo resist is provided to cover a predetermined area adjacent to the through hole on the first surface and the second surface of the substrate to expose a part of area of the first surface adjacent to the first part and a part of area of the second surface adjacent to the second part. Please refer to FIG. 3. A photo resist 130, 140 is respectively provided to cover a predetermined area adjacent to the through hole 120 on a first surface 112 and a second surface 114 opposite to the first surface 112 of the substrate 110 to expose a part of area of the first surface 112 adjacent to the first part 122 and a part of area of the second surface 114 adjacent to the second part 124. The distance between the photo resist 130, 140 and an edge of the through hole 120 may affect the shape of dumbbell-shaped through hole 120 during the later etching process. Specifically, the longer the distance is, the more difference of the diameters at the first part 122 and the second part 124 than the third part 126 of the through hole 120 is, The shorter the distance is, the less difference of the diameters at the first part 122 and the second part 124 than the third part 126 of the through hole 120 is.

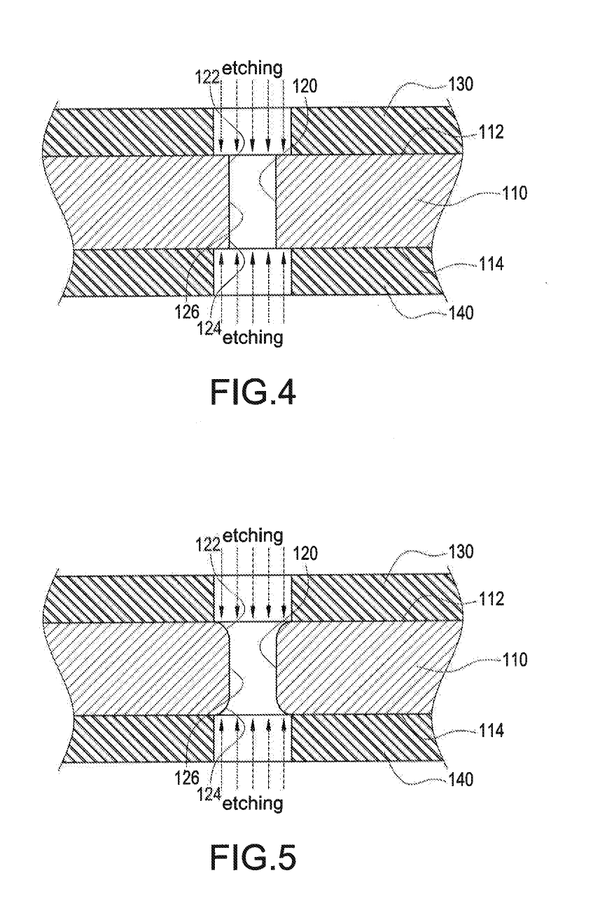

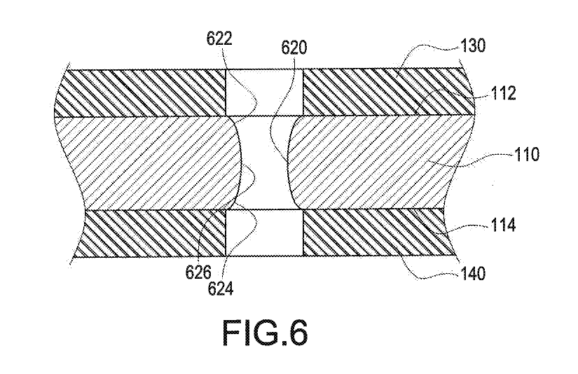

Next, in step S130, an etching process is performed to the through hole, and the diameter of the first part 122 and second part 124 of the through hole gets narrower toward the third part 126 respectively. Please refer to FIG. 4. The substrate 110 is dipped into an etching solution with 50-70° C. for 0.5-1 hour. The composition of the etching solution can be prepared according to the material of substrate and the dimension of the through hole. In the embodiment, the composition of the etching solution includes 50-70 wt % H3PO4, 10-20 wt % HNO3, 10-20 wt % CH3COOH and 5-10 wt % deionized water. Also, in order to increase the etching effect, a clean process may be performed by ultrasonic vibration before step S130 to remove the fragment within the through hole 120. The clean process is performed about 5-10 minutes, As shown in FIG. 5, the etching solution may enter the through hole 120 and etch the substrate 110 from the first surface 112 and the second surface 114 for a period of time so that the diameter of the first part 122 and the second part 124 is getting narrower toward the third part 126, but the third part 126 keeps substantially the same diameter, shown as the through hole 120 in FIG. 5. As shown in FIG. 6, after etching a longer time, the diameter of the first part 622 and the second part 624 is getting narrower toward the third part 626, and the diameter of the third part 626 is getting narrower from the first part 622 and the second part 624 toward the center of the through hole 620.

Specifically, as shown in FIG. 5, the through hole 120 of the substrate 110 has a shape which is getting narrower toward the third part 126 from the first part 122 and the second part 124, but the third part 126 keeps substantially the same diameter. The through hole 120 is filled with conductive material to form a conductive pillar by subsequent electroplating process. Because the diameters of the first part 122 and the second part 124 are larger than the diameter of the third part 126 of the through hole 120, the electroplating solution can flow into the through hole 120 without obstruction, and thus the unfilled area of conductive material in a central part of the through hole 120 can be prevented. Alternatively, the through hole 120 may advantageously form conductive pillars by the sputtering process, and prevent the through hole 120 broken.

As shown in FIG. 6, the through hole 620 of the substrate 110 has a shape which is getting narrower toward the third part 626 from the first part 622 and the second part 624. The through hole 620 can be filled with conductive material to form a conductive pillar by subsequent electroplating process. Because the diameters of the first part 622 and the second part 624 are larger than the diameter of the third part 626 of the through hole 620, the electroplating solution can flow into the through hole 620 without obstruction, and thus the unfilled area of conductive material in the central part of the through hole 620 can be prevented. Alternatively, the through hole 620 may advantageously form conductive pillars by the sputtering process, and prevent the through hole 620 broken.

As shown in FIG. 5, the circuit board that is manufactured by the method of the invention comprises a substrate 110; and a through hole 120 formed in the substrate 110, wherein the through hole 120 has a shape which is getting narrower toward a central part from two surfaces of the substrate 110, and the central part of the through hole 120 keeps substantially the same diameter. The through hole 120 has a diameter about 60-100 μm on the surface of the substrate 110. Also, the through hole 120 has a diameter at the central part of the substrate 110 less about 20-30 μm than the diameter on the surface of the substrate 110.

As shown in FIG. 6, the circuit board that is manufactured by the method of the invention comprises a substrate 110; and a through hole 620 formed in the substrate 110, wherein the through hole 620 has a shape which is getting narrower toward a central part thereof from two surfaces of the substrate 110, while the central part of the through hole 620 does not keep substantially the same diameter. The through hole 620 has a diameter about 60-100 μm on the surface of the substrate 110. Also, the through hole 620 has a diameter at the central part of the substrate 110 less about 20-30 μm than the diameter on the surface of the substrate 110.

The substrate 110 such as ceramic substrate is suitably used as a carrier, for example heat dissipative substrate of light emitting diodes, of high power electrical elements. Alternatively, the substrate 110 may be metallic substrate having the material such as aluminum, aluminum alloy, copper or copper alloy. The through hole 120 of the substrate 110 of the invention is formed by an etching process, and the surface roughness Ra of inner wall of the through hole 120 is about 0.3-0.4 μm. After the etching process, the surface roughness Ra of inner wall of the through hole 12 may increase to 0.3 μm from 0.2 μm of the laser drilling. In contrast, if a sandblasting process is performed to form the dumbbell-shaped through hole, the surface roughness Ra of inner wall of the through hole may exceed 0.5 μm. It is disadvantageous for performing the thin film process such as sputtering process or electroplating process that the surface roughness Ra of inner wall of the through hole 12 is too high or too low. The surface roughness Ra of inner wall of the through hole 12 having a shape of dumbbell that is manufactured by the invention is advantageous for performing the thin film process due to the surface roughness Ra is between the laser drilling and the sandblasting process.

While the invention is described in by way of examples and in terms of preferred embodiments, it is to be understood that the invention is not limited thereto. On the contrary; the aim is to cover all modifications, alternatives and equivalents falling within the spirit and scope of the invention as defined by the appended claims.

What is claimed is:

1. A method for manufacturing a circuit board, comprising steps of:
(a) forming a through hole in a substrate having a first surface and a second surface opposite to the first surface, wherein the through hole includes a first part adjacent to the first surface, a second part adjacent to the second surface and a third part located between the first part and the second part;
(b) providing a photo resist to cover a predetermined area adjacent to the through hole on the first surface and the second surface of the substrate to expose a part of area of the first surface adjacent to the first part and a part of area of the second surface adjacent to the second part; and
(c) performing an etching process to make the diameters of the first part and the second part of the through hole get narrower toward the third part.

2. The method for manufacturing a circuit board of claim 1, further comprising a clean process for the substrate before step (c).

3. The method for manufacturing a circuit board of claim 2, wherein the clean process includes a step of cleaning the substrate by ultrasonic vibration.

4. The method for manufacturing a circuit board of claim 2, wherein the clean process is performed for 5-10 minutes.

5. The method for manufacturing a circuit board of claim 1, wherein the etching process of step (c) uses an etching solution including 50-70 wt % H3PO4, 10-20 wt % HNO3, 10-20 wt % CH3COOH and 5-10 wt % deionized water.

6. The method for manufacturing a circuit board of claim 1, wherein the etching process of step (c) is performed by immersing the substrate into an etching solution with a temperature of 50-70° C. for 0.5-1 hour.

7. The method for manufacturing a circuit board of claim 1, wherein the through hole of step (a) may be formed by mechanical drilling or laser drilling.

8. The method for manufacturing a circuit board of claim 1, wherein the third part of the through hole has substantially the same diameter.

9. The method for manufacturing a circuit board of claim 1, further comprising filling a conductive material in the through hole to form a conductive pillar by an electroplating process after step (c).

10. The method for manufacturing a circuit board of claim 1, wherein an inner wall of the through hole has a surface roughness (Ra) of 0.3-0.4 μm after step (c).

11. The method for manufacturing a circuit board of claim 11, wherein the through hole has a largest diameter of 60-100 μm after step (c).

12. The method for manufacturing a circuit board of claim 11, wherein the through hole has a diameter at the central part less 20-30 μm than the largest diameter.

13. A circuit board, comprising:
a substrate having a first surface and a second surface opposite to the first surface; and
a through hole formed in the substrate, wherein the through hole has a diameter getting narrower toward a central part of the through hole from the first and the second surfaces of the substrate, and an inner wall of the through hole has a surface roughness (Ra) of 0.3-0.4 μm.

14. The circuit board of claim 13, wherein the through hole has a largest diameter of 60-100 μm.

15. The circuit board of claim 14, wherein the through hole has a diameter at the central part less 20-30 μm than the largest diameter.

16. The circuit board of claim 13, wherein the central part of the through hole has substantially the same diameter.

17. The circuit board of claim 13, wherein the substrate includes one of a ceramic subs and a metal substrate.

18. The circuit board of claim 13, being a heat dissipative substrate for a light emitting device.
